(19) United States
(12) Patent Application Publication
(10) Pub. No.: US 2009/0120169 A1
(43) Pub. Date: May 14, 2009

(54) FLUID SENSOR AND METHODS OF MAKING COMPONENTS THEREOF

(76) Inventors: William H. Chandler,, JR., Milpitas, CA (US); Douglas B. McNeil, Monte Sereno, CA (US); Gregory Ray Goslin, Los Gatos, CA (US)

Correspondence Address: SENNIGER POWERS LLP, 100 NORTH BROADWAY, 17TH FLOOR, ST LOUIS, MO, 63102, US

(21) Appl. No.: 11/938,621

(22) Filed: Nov. 12, 2007

(51) Int. Cl. G01N 11/16; H01L 41/22

(52) U.S. Cl. 73/54.41; 29/25.35

(57) ABSTRACT

A fluid sensor has an electrically grounded header and a plurality of feedthrough conductors extending through the header between opposite ends of the header. The feedthrough conductors are connected to a piezoelectric tuning fork resonator. A temperature sensor is adjacent the tuning fork resonator. A shroud partially encloses the tuning fork resonator and temperature sensor. A printed circuit board is in conductive electrical contact with the feedthrough conductors. The printed circuit board includes an ASIC chip operable to transmit a variable frequency signal to the tuning fork resonator through the feedthrough conductors to oscillate the tuning fork resonator and to monitor impedance of the tuning fork resonator as a function of frequency. The ASIC chip is spaced from the feedthrough conductors a distance of no more than about 2 mm. The printed circuit board is spaced from the tuning fork a distance of no more than about 20 mm.

### FIELD OF INVENTION

The present invention relates generally to fluid sensors, and more particularly, to methods and apparatus for analyzing one or more properties of a fluid using a mechanical resonator. Some aspects of the invention relate to methods of manufacturing a fluid sensor comprising a mechanical resonator.

### BACKGROUND

Mechanical resonators can be used to sense properties of fluids. For example, it is possible to determine properties of a fluid (e.g., viscosity, density, and dielectric constant) by analyzing a response of a mechanical resonator oscillating while it is in contact with the fluid as set forth in U.S. Pat. Nos. 6,182,499; 6,393,895; 6,401,519; 6,494,079; 6,873,916; 7,043969; 7,210,332; and 7,272,525 and U.S. Patent App. Pub. Nos. 20050145019; 20050262944; and 20070017291, the contents of which are each hereby incorporated herein by reference.

### SUMMARY

In one aspect of the invention a fluid sensor for determining properties of a fluid includes a header assembly. The header assembly includes an electrically grounded header and a plurality of feedthrough conductors extending through the header between opposite ends of the header. Each of the feedthrough conductors is surrounded by an electrically insulating sheath. The feedthrough conductors are fused to the sheaths and the sheaths are fused to the header. The sensor also includes a tuning fork resonator having a base portion and a pair of tines extending from the base portion. Each of the tines includes a piezoelectric substrate and electrodes on the substrate for applying an electric field to the substrate. Some of the feedthrough conductors are in conductive electrical contact with the electrodes. A temperature sensor is in conductive electrical contact with some of the feedthrough conductors. The temperature sensor is spaced from the tuning fork resonator a distance that is no more than about 2 mm. An electrically grounded shroud partially encloses the tuning fork resonator and temperature sensor. The shroud has a substantially cylindrical wall extending circumferentially around the tuning fork resonator and temperature sensor. The shroud includes a plurality of openings in the wall for allowing said fluid to enter the shroud and contact the tuning fork resonator and temperature sensor. The shroud is secured to the header assembly. A fitting is adapted be installed in an opening of a support structure. The fitting has a central opening. The header assembly is received in the central opening and secured to the fitting. A printed circuit board is in conductive electrical contact with the feedthrough conductors. The printed circuit board includes an ASIC chip operable to transmit a variable frequency signal to the electrodes on the tuning fork resonator through the feedthrough conductors to energize the electrodes so the tines oscillate in opposite phase and to monitor impedance of the tuning fork resonator as a function of frequency. The ASIC chip is spaced from the feedthrough conductors a distance of no more than about 2 mm. The printed circuit board is spaced from the electrodes on the tuning fork a distance of no more than about 20 mm.

Other objects and features will be in part apparent and in part pointed out hereinafter.

### BRIEF DESCRIPTION OF THE DRAWINGS

FIG. 1 is a perspective of one embodiment of a fluid sensor of the present invention;

FIG. 2 is a side elevation of the fluid sensor installed in an opening of a support structure;

FIG. 3 is a front elevation of the fluid sensor;

FIG. 4 is a perspective of a cross section of the fluid sensor taken in a plane including line 4-4 on FIG. 3 and with a portion of a header removed to show feedthrough conductors;

FIG. 4A is a cross section of the fluid sensor taken in a plane including line 4A-4A on FIG. 1;

FIG. 5 is a perspective of a cross section of the fluid sensor taken in a plane including line 5-5 on FIG. 3;

FIG. 6 is a perspective of a cross section of the fluid sensor taken in a plane including line 6-6 on FIG. 3;

FIG. 7 is an enlarged side view of one embodiment of a sensing portion of the fluid sensor with a shroud thereof removed and other parts of the sensor broken away;

FIG. 7A is an enlarged side view similar to FIG. 7, but from the opposite side of the fluid sensor;

FIG. 8 is a cross section of one embodiment of a tuning fork resonator of the fluid sensor taken in a plane including the line 8-8 on FIG. 7, other parts of the fluid sensor being omitted to improve clarity;

FIG. 9 is a perspective of one embodiment of a header assembly connected to the sensing portion of the sensor with the shroud and other parts of the sensor omitted for clarity;

FIG. 10 is a perspective similar to FIG. 9, but showing the shroud;

FIG. 11 is a perspective similar to FIG. 10 illustrating oscillating movement of the tines of the tuning fork within an oscillation plane;

FIG. 11A is perspective similar to FIG. 10, but showing a different embodiment of a shroud;

FIG. 12 is a perspective of the fluid sensor showing an electrical connector thereof exploded from other parts of the sensor;

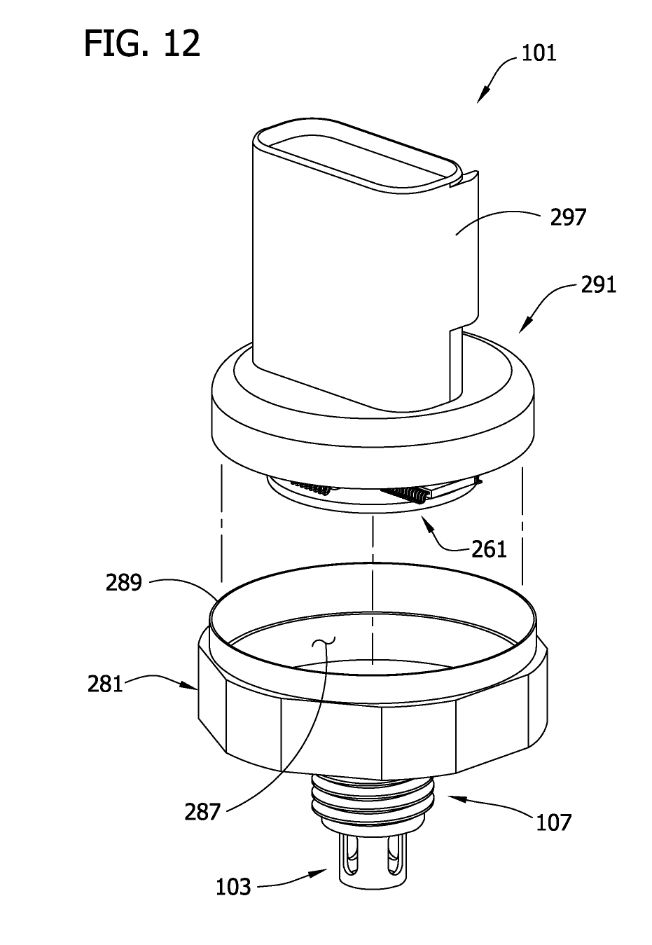

FIG. 13 is a perspective of one embodiment of a PCB assembly in a flat configuration; and

FIG. 14 is a perspective of the PCB assembly in a more compact configuration.

Corresponding reference characters indicate corresponding parts throughout the drawings.

### DETAILED DESCRIPTION

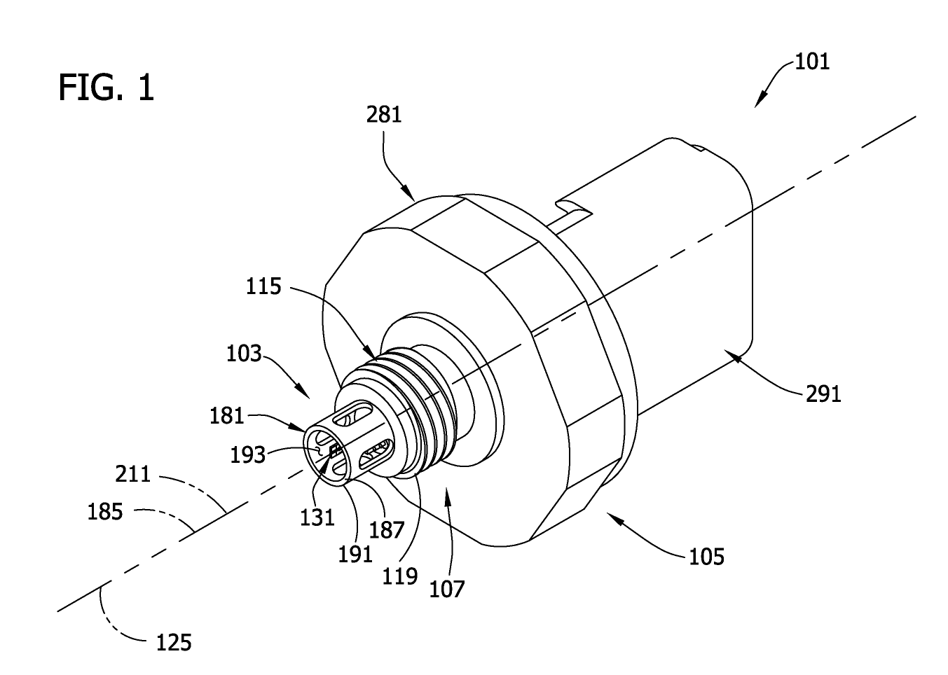

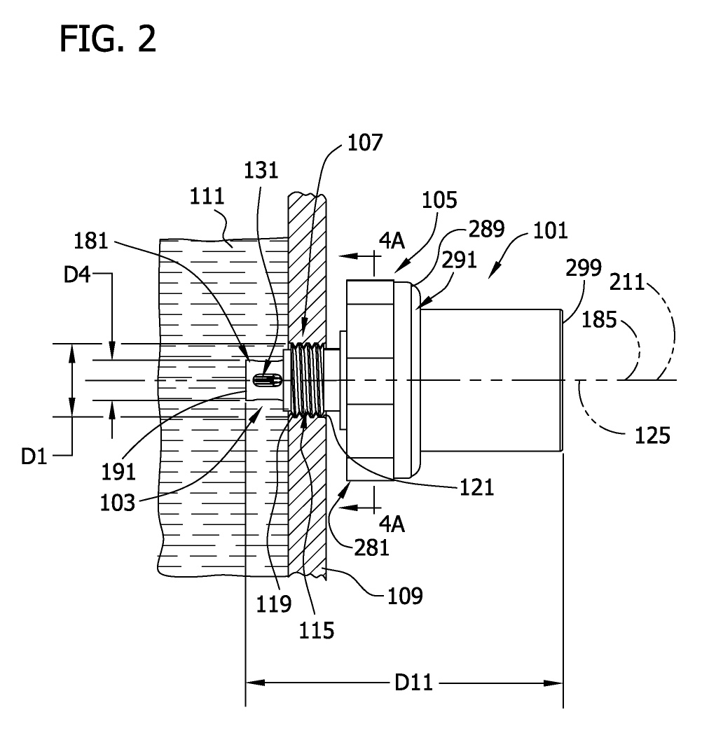

Referring now to the drawings, first to FIGS. 1 and 2 in particular, one embodiment of a fluid sensor is generally designated 101. The sensor 101 has a fluid sensing portion 103, a processing portion 105, and a mounting portion 107 that is positioned intermediate the sensing portion and the processing portion.

As illustrated in FIG. 2, the mounting portion 107 allows the fluid sensor 101 to be releasably secured to a support structure 109 (e.g., a containment wall of a reservoir or conduit containing fluid 111 to be analyzed) for maintaining the sensing portion 103 of the fluid sensor in a desired position relative to the fluid. Depending on the particular application, for example, the mounting portion 107 can be secured to the support structure 109 to maintain the fluid sensor 101 in a position in which the sensing portion 103 is submerged in the fluid 111 (as illustrated in FIG. 2, for example) or at least intermittently in contact with the fluid.

In the illustrated embodiment, the mounting portion 107 includes the threaded ring 115 of a fitting 117 having external threads 119 for screwing the fluid sensor 101 into a threaded opening 121 in the support structure 109 so the fluid 111 to be analyzed is on the same side of the support structure as the sensing portion 103 and the processing portion 105 is on the opposite side of the support structure relative to the sensing portion. In one embodiment, the fitting 117 is made of brass, however the fitting can be made from other materials (such as aluminum and the like) within the scope of the invention. In the illustrated embodiment, the fitting 117 includes a housing 281, which is described in more detail below, secured to the threaded ring 155 (e.g., by being integral therewith) and on the opposite side thereof relative to the sensing portion 103 of the sensor 101.

The threaded ring 115 suitably has a standardized external diameter D1 and thread type (e.g., a diameter and thread type used in the truck and automotive industry to install various sensors in vehicles), thereby allowing the fluid sensor 101 to be installed in place of other sensors that use an equivalent mounting portion with only limited or substantially no changes to the associated manufacturing methods. In one embodiment, for example, the threaded ring 115 of the fitting 117 complies with SAE J1453. The threaded ring 115 of the fitting 117 suitably has a relatively small external diameter D1 (e.g., an external diameter of no more than about 13 mm), thereby allowing the fluid sensor 101 to be installed in a relatively small opening 121. Although the illustrated embodiment of the fluid sensor 101 is adapted for making a threaded connection with the support structure 109, other mounting systems for releasably securing the fluid sensor to a support structure can be used within the scope of the invention.

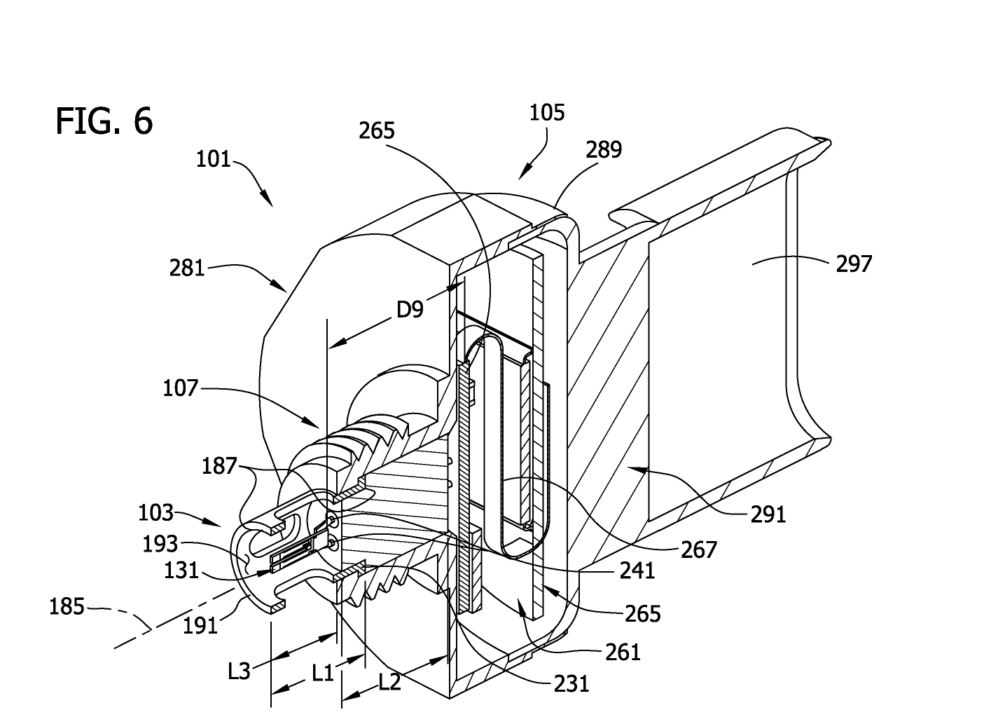

As illustrated in FIG. 6, the sensing portion 103 of the fluid sensor 101 includes a mechanical resonator 131 positioned for contacting the fluid 111 to be analyzed. The sensing portion 103 is arranged relative to the mounting portion 107 so the sensing portion extends away from the support structure 109 when the mounting portion is secured thereto. For instance, the sensing portion 103 suitably extends away from the support structure 109. As indicated in FIG. 2, for example, the sensing portion 103 extends axially away from the threaded ring 115 generally along a central axis 125 thereof (e.g., substantially parallel to the central axis of the threaded ring). Accordingly, when the sensor 101 is installed in a support structure 109 having a generally planar configuration proximate the opening 121 the sensing portion 103 extends generally away from the support structure and protrudes into the liquid 111.

The mechanical resonator 131 is suitably a flexural resonator, which means the oscillation of the resonator includes bending of some portion of the resonator. Because of the bending motion of the flexural resonator 131, a portion of the resonator is translated through the fluid 111 to be analyzed during oscillation of the flexural resonator while the resonator is in contact with the fluid. In the illustrated embodiment, for example, the mechanical resonator 131 comprises a tuning fork resonator. Additional details regarding suitable mechanical resonator fluid sensors, including fluid sensors that use flexural resonators in general, and tuning forks in particular, are provided in U.S. Pat. Nos. 6,182,499; 6,393,895; 6,401,519; 6,494,079; 6,873,916; 7,043,969; 7,210,332; and 7,272,525 and U.S. Patent App. Pub. Nos. 20050145019; 20050262944; and 20070017291, the contents of which have already been incorporated by reference above.

Briefly, as set forth in the foregoing patents and published patent applications, various properties of the fluid 111 can be determined by monitoring the response of the mechanical resonator 131 to the dampening effects of the fluid on the resonator's oscillation. By way of example but not limitation, the response of the flexural mechanical resonator 131 to oscillation of the resonator while it is in contact with the fluid can be used to determine the viscosity and density of the fluid 111 independently and simultaneously. In some embodiments, the response of the flexural mechanical resonator 131 allows the viscosity, density and an electrical property (e.g., dielectric constant) of the fluid 111 to be determined simultaneously and independently.

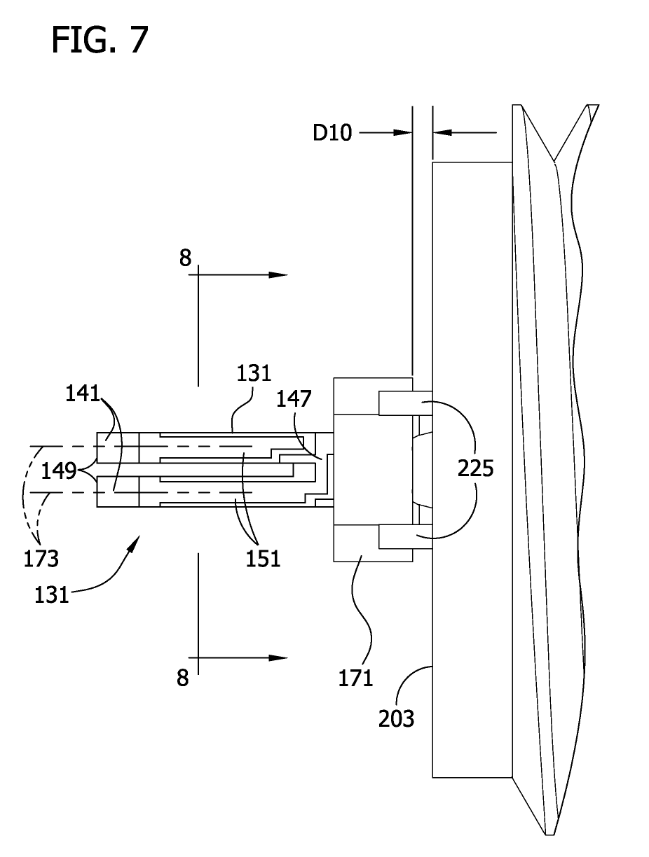

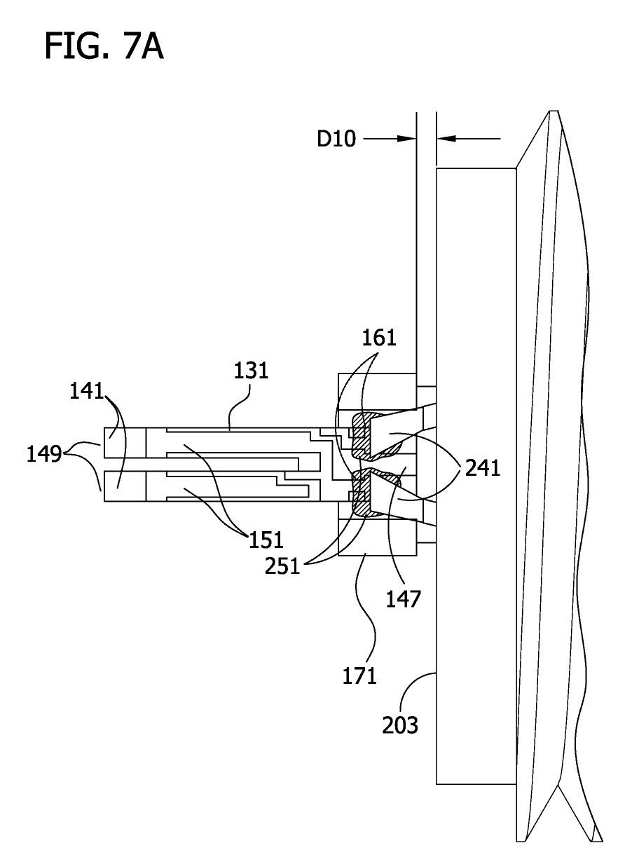

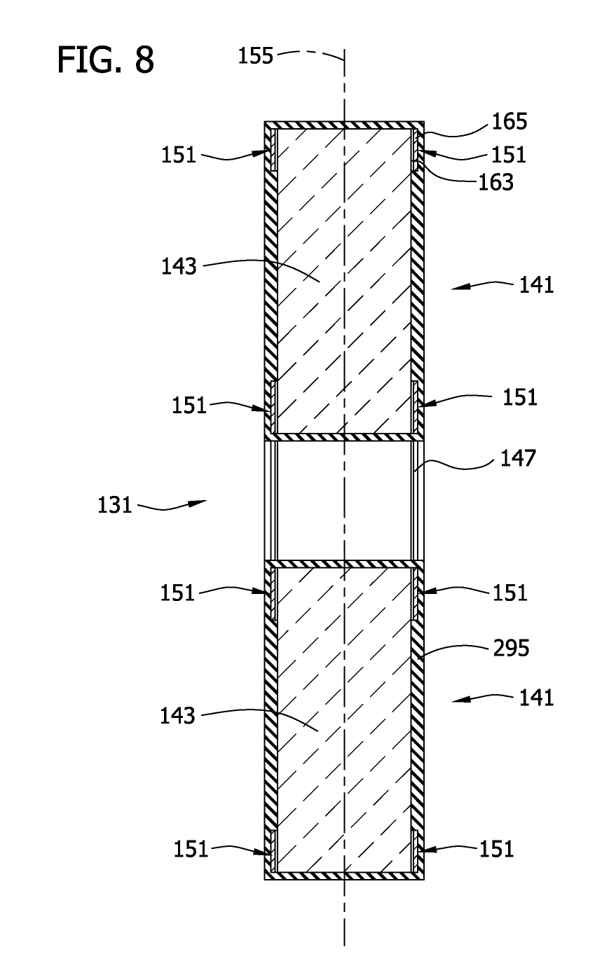

Referring to FIGS. 7-8, the tuning fork resonator 131 shown in the illustrated embodiment includes a pair of tines 141 made from a substrate 143 comprising a piezoelectric material, such as quartz, lithium niobate, lead zirconate titanate (PZT), langasite, or the like. Each of the tines 141 suitably extends away from an integral base 147 of the resonator to a free end 149 of the respective tine. Because of the piezoelectric material 143 in the tine 141, each of the tines can be made to flex (i.e., bend) by subjecting the piezoelectric material to an electric field generated by energizing electrodes 151 associated with the respective tine.

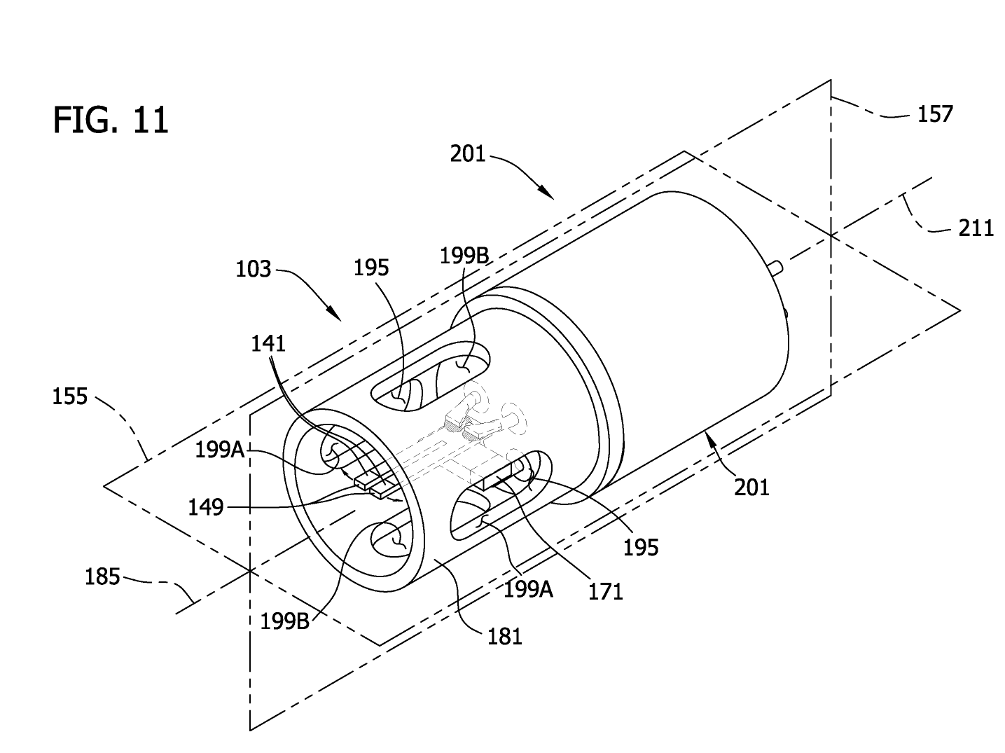

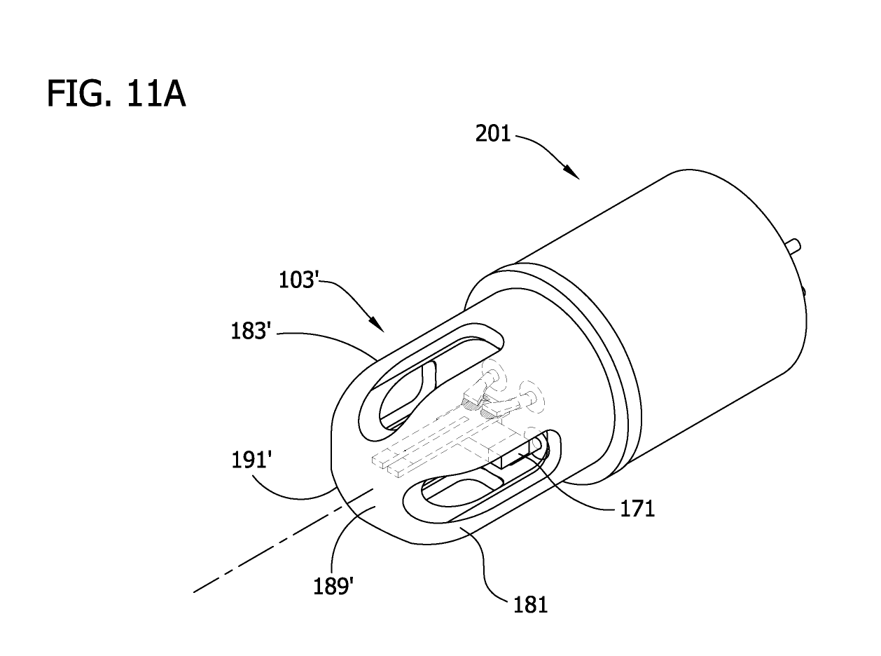

The processing portion 105 of the sensor 101 suitably includes a drive system 271, described later, adapted to energize the electrodes 151 to apply electric fields to the piezoelectric material 143 in the tines 141. The electrodes 151 are suitably energized in a sequence that in combination with the orientation of the piezoelectric material 143 results in oscillation of the tines 141 in opposite phase relative to one another. As indicated by the arrows in FIG. 11, for example, the tines 141 in this embodiment oscillate in opposite phase substantially within the same oscillation plane 155. The oscillation plane 155 in this embodiment is generally parallel to the tines 141 and intersects the base 147 of the tuning fork resonator 131.

The electrodes 151 are suitably on external surfaces of the piezoelectric substrate 143, as indicated in FIG. 8. For example, the electrodes 151 suitably comprise a thin layer 163 of electrically conductive material (e.g., metal) bonded to and in contact with the piezoelectric substrate 143 at selected locations. The electrodes 151 in the illustrated embodiment are configured to include relatively broad contact pads 161 (FIG. 7A) on the base 147 of the tuning fork resonator 131, which facilitate electrical connection of the electrodes to the processing portion 105 of the sensor 101, as will be described in more detail below. As illustrated in FIG. 8, the electrodes 151 and contact pads 161 of this embodiment comprise a thin layer comprising a first metal 163 in contact with and bonded to the piezoelectric material 143 and a second layer 165 overlying the first layer and comprising a different metal that has greater resistance to corrosion than the first metal.

For example, in one embodiment, the piezoelectric material 143 comprises quartz and the electrodes 151 comprise a layer 163 comprising Chromium bonded to the quartz and a layer 165 comprising Gold overlying the Chromium layer. In this embodiment, the Chromium layer 163 is suitably a relatively thinner layer (e.g., a layer having a thickness in the range of about 10 nm to about 20 nm) and the Gold layer 165 is a relatively thicker layer (e.g., a layer having a thickness in the range of about 170 nm to about 230 nm). Gold has been found to be relatively resistant to corrosion by some fluids of interest, such as engine oil, petroleum products (e.g., petroleum fuels), hydraulic fluids, halogenated refrigerants, and the like. However, the applicants have also found that it can be difficult to bond Gold to quartz. On the other hand, it has been determined that Chromium bonds to quartz better than Gold, although Chromium is not as resistant to corrosion as Gold. Other conductive materials can be used to make the electrodes and/or contact pads within the scope of the invention. The layers 163, 165 of the electrodes can be applied to the piezoelectric substrate 143 by electroplating, chemical vapor deposition and/or other suitable thin layer application technologies.

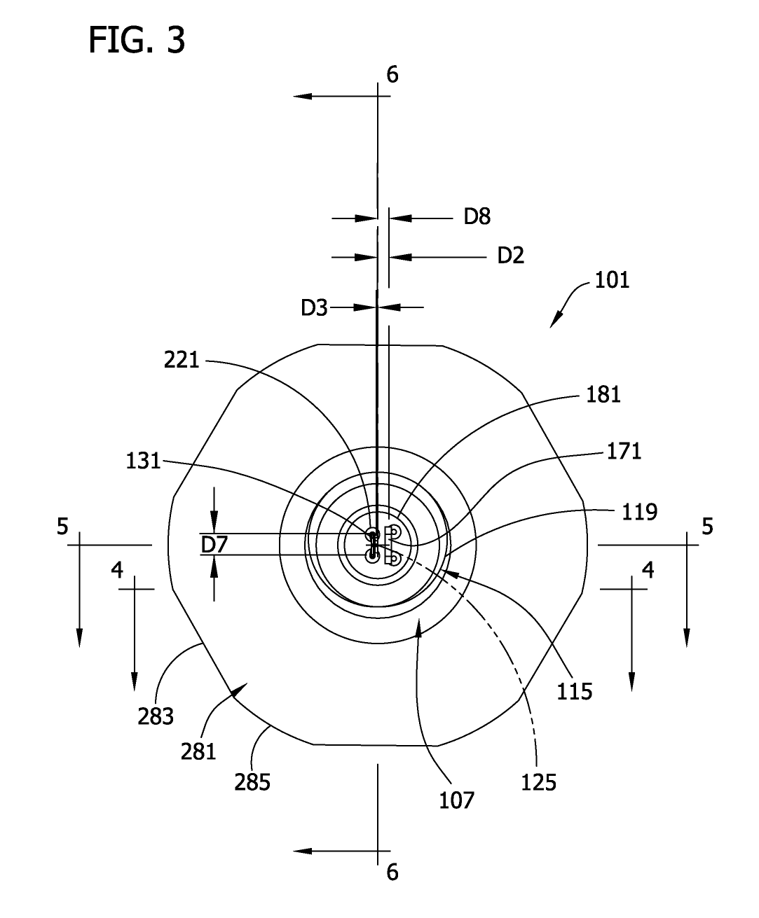

The sensing portion 103 of the fluid sensor 101 optionally includes a temperature sensor 171 (e.g., an RTD temperature sensor) positioned adjacent the mechanical resonator 131, as indicated in FIGS. 3, 4, 5, and 7. For example, in one embodiment, the temperature sensor 171 is spaced a distance D2 (FIG. 3) that is no more than about 2 mm from the mechanical resonator 131. In the embodiment illustrated in the drawings, the temperature sensor 171 is positioned adjacent the base 147 of the tuning fork resonator 131. As indicated in FIG. 7, for example, the temperature sensor 171 in this embodiment is out of axial registration with the tines 141 of the tuning fork resonator 131 (relative to longitudinal axes 173 of the tines). The temperature sensor 171 is also offset from the oscillation plane 155 (FIG. 11) of the tuning fork tines 141 in the illustrated embodiment, as indicated in FIGS. 3 and 99. Positioning the temperature sensor 171 so it is adjacent the base 147 rather than the tines 141 and/or offset from the oscillation plane 155 allows the temperature sensor to be positioned relatively close to the tuning fork resonator 131 without interfering with oscillation of the tines and can also limit the influence (e.g., noise) that proximity of the temperature sensor to the tuning fork resonator may have on the response thereof the fluid 111 to be analyzed.

The temperature sensor 171 provides information about the temperature of the fluid 111 interacting with the mechanical resonator 131, which is valuable because it can indicate whether a change in another property of the fluid (e.g., viscosity) is associated with a temperature change rather than degradation, contamination, or some other process affecting the fluid properties. The relatively close proximity of the temperature sensor 171 to the mechanical resonator 131 makes the fluid sensor 101 less susceptible to thermal gradients in the fluid 111, which could otherwise result in an undesirably large difference between the temperature measured by the temperature sensor and the actual temperature of the fluid that is interacting with the mechanical resonator.

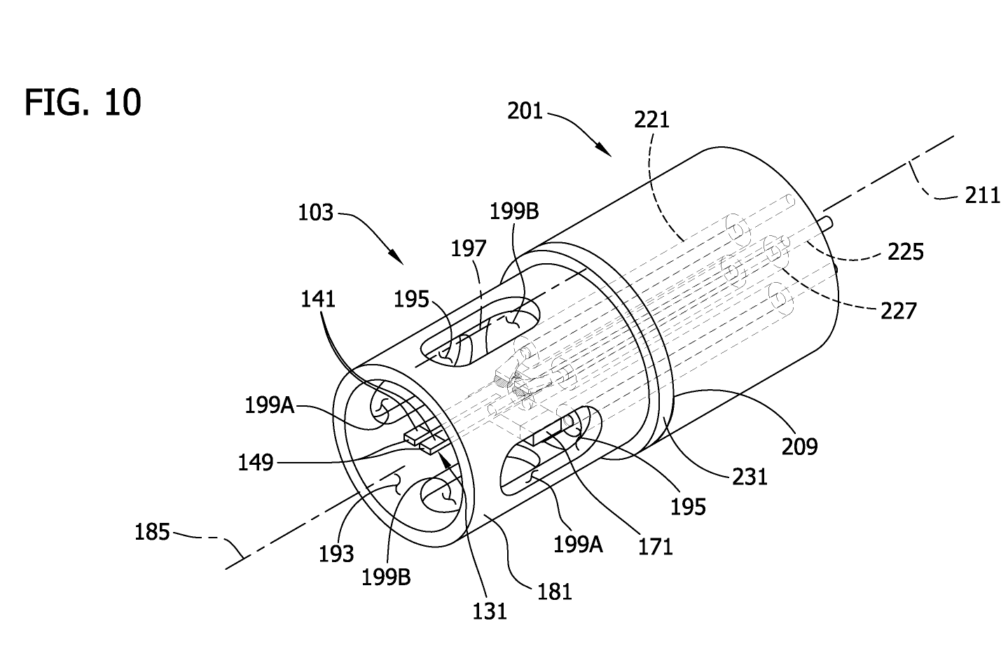

As best illustrated in FIGS. 10 and 11, the tuning fork resonator 131 and the temperature sensor 171 of this embodiment are partially enclosed in a shroud 181 to protect the tuning fork resonator and/or temperature sensor from impact with any debris that may be in the fluid 111 to be analyzed. The shroud 181 also protects the tuning fork resonator 131 and temperature sensor 171 from being damaged by any accidental contact between the sensing portion and the support structure 109 during installation. The shroud 181 is suitably constructed of a metallic material and electrically grounded (e.g., by electrically grounding the fitting 117 and maintaining electrical contact between the shroud and the fitting). Electrically grounding the shroud 181 in this manner can yield decreased noise levels in the response of the mechanical resonator 131.

In the illustrated embodiment, for example, the shroud 181 comprises a wall 183 (e.g., a substantially right cylindrical wall having a circular cross section) extending circumferentially around the tuning fork resonator 131 and temperature sensor 171. The shroud 181 in this embodiment has a central axis 185 extending generally between open axial ends 187 of the shroud. In one embodiment, the axial length L1 of the shroud 181 is suitably in the range of about 7 mm to about 9 mm (e.g., about 8 mm). As illustrated in FIG. 6, the axial length L1 of the shroud 181 is suitably long enough that the shroud extends beyond the ends of tines 149 of the tuning fork resonator 131. The tuning fork resonator 131 is suitably positioned centrally in the shroud 181. For example, in one embodiment, the tines 141 of the tuning fork resonator 131 are spaced a distance D3 (FIG. 3) of no more than about 2 mm from the central axis 185 of the shroud 181. The temperature sensor 171 is suitably offset from the central axis 185 of the shroud 181 a distance D8 (FIG. 3) that is larger than a distance D3 between the tuning fork resonator 131 and the central axis of the shroud.

As illustrated in FIG. 2, the tuning fork resonator 131 and the temperature sensor 171 are suitably sized, shaped, and/or arranged so they can pass through the opening 121 in the support structure 109 together as the fluid sensor 101 is being installed in (e.g., screwed into) the opening. In the illustrated embodiment, the shroud 181 is the component of the sensing portion 103 having the largest dimensions and other parts of the sensing portion, including the mechanical resonator 131 and the temperature sensor 171, are positioned in the shroud. In this embodiment, the shroud 181 is also sized and shaped to allow the shroud, to pass through the opening 121 in the support structure along with the rest of the sensing portion 103 as the fluid sensor 101 is being installed in the opening. Accordingly, the shroud 181 suitably has a diameter D4 (FIG. 2) that is smaller than the external diameter D1 of the threaded ring 115. For example, the shroud 181 suitably has a diameter D4 that is no more than about 5 mm to about 8 mm. The relatively small diameter D4 of the shroud 181 and the relatively small size of the sensing portion 103 overall also permit the sensing portion of the fluid sensor 101 to fit in relatively tight spaces.

As illustrated in FIG. 1, one of the open axial ends 187 of the shroud 181 is at the distal end 191 of the sensing portion 103 of the fluid sensor 101 and provides an opening 193 allowing the fluid 111 to be analyzed to enter the shroud and contact the tuning fork resonator 131 and temperatures sensor 171. Referring to FIGS. 10 and 11, in this embodiment, the shroud 181 has additional openings 195 (e.g., four additional openings in the illustrated embodiment) in the cylindrical wall 183, which also allow fluid 111 to enter the shroud and contact the tuning fork resonator 131 and temperature sensor 171. The additional openings 195 in this embodiment are elongate in shape and have longitudinal axes 197 that are generally aligned with (e.g., substantially parallel to) the tines 141 of the tuning fork resonator when the tines are in their resting position. The openings 195 are suitably spaced substantially equally from one another circumferentially around the wall 183 of the shroud 181. The openings 195 are also in axial registration (relative to the central axis 185 of the shroud 181) with at least portions of the tines 141 of the tuning fork resonator 131.

In one embodiment, the openings 195 include at least one pair of openings (e.g., two pairs 199A, 199B in the illustrated embodiment) arranged so the openings in the pair are located on opposite sides of the central axis 185 of the shroud 181 relative to one another, thereby allowing fluid to flow into the shroud through one opening of the pair of openings and out of the shroud through the other opening of that pair in generally the same direction. The shroud 181 in the illustrated embodiment includes one pair of openings 199A that are generally aligned with the oscillation plane 155 of the tuning fork tines 141. Another pair of openings 199B in this embodiment is generally aligned with a plane 157 that includes the central axis 185 of the shroud 181 and that is generally perpendicular to the oscillation plane 155. It is understood that the number of openings in the shroud, the configuration of the openings, and their arrangement relative to other parts of the fluid sensor can vary within the scope of the invention.

FIG. 11A illustrates another embodiment of a shroud 181′ which is substantially the same as the shroud 181 described above (except as noted) and which is substantially interchangeable with the shroud described above. The shroud 181′ shown in FIG. 11A has a dome shaped cover 189′ (e.g., a cover that is integral with the wall 183′) at the distal end 191′ of the sensing portion 103′ covering the tuning fork resonator 131 and temperature sensor 171. Accordingly, the dome shaped cover 189′ provides additional protection for the tuning fork resonator 131 and temperature sensor 171 during installation and in use. The cover 189′ is suitably grounded in the same manner as the rest of the shroud 181′, as described above.

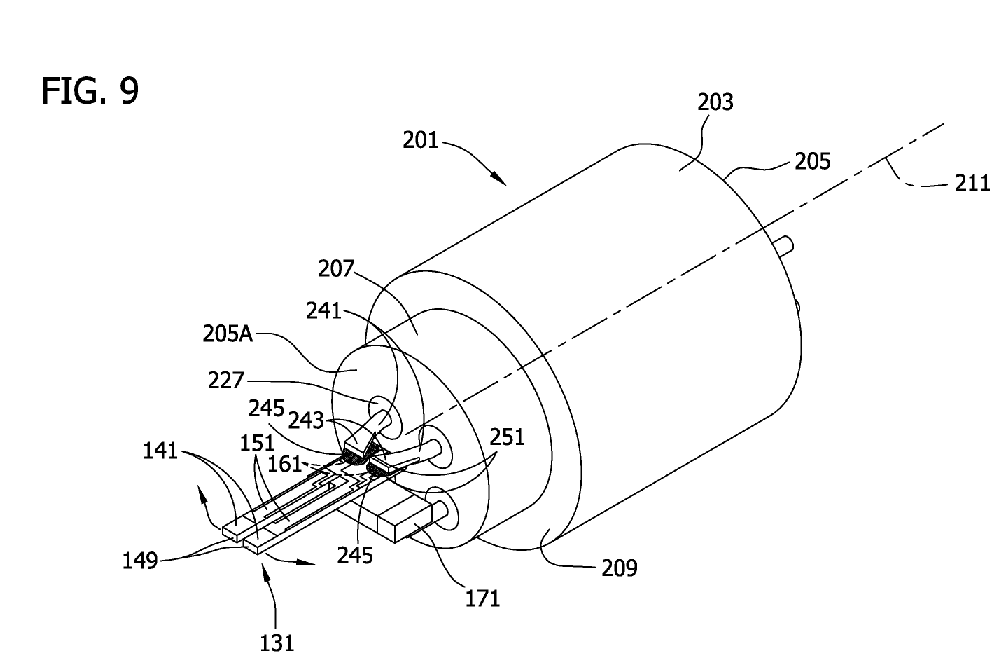

The tuning fork resonator 131 and temperature sensor 171 are both secured to a header assembly 201. As illustrated in FIG. 9, the header assembly 201 of this embodiment includes a generally cylindrical header 203 extending a length L2 (FIG. 6) in the range of about 8 mm to about 12 mm between opposite ends 205 along a central axis 211, which in the illustrated embodiment is aligned with the central axis 185 of the shroud 181. In one embodiment, the header 203 is made of stainless steel. However, other materials (e.g., aluminum or brass) can also be used within the scope of the invention. The distal end 205A of the header 203 has a smaller diameter end portion 207 resulting in a radial annular shoulder 209 facing the tuning fork resonator 131 and temperature sensor 171.

A plurality of through holes 221 (e.g., four through holes) extend through the header 203 generally parallel to its central axis 211. As indicated in FIGS. 3 and 10, the through holes 221 are suitably arranged in a relatively compact geometric pattern generally centered on the central axis 211 of the header 203. Accordingly, each of the through holes 221 in the illustrated embodiment is offset from the central axis 211 of the header 203. Each of the through holes 221 in the illustrated embodiment is also spaced a distance D7 (FIG. 3) from its nearest neighboring through hole. In one embodiment of the invention, for example, the distance D7 is suitably at least about 2 mm. It is noted that the distance to the nearest neighboring through hole may vary from one through hole to another within the scope of the invention.

Electrically conductive feedthrough conductors 225 (e.g., pins) extend between the ends 205 of the header through the through holes 221. Each of the feedthrough conductors 225 is suitably surrounded by a protective and electrically insulating sheath 227. In one embodiment, for example, the sheaths 227 are made from a heat resistant glass. The feedthrough conductors 225 are suitably made from an electrically conductive material selected to match the thermal expansion coefficient of the protective sheaths 227. For example, the protective sheaths 227 are suitably made from a borosilicate glass and the feedthrough conductors 225 are suitably made from an alloy comprising nickel, cobalt, and iron (e.g., Kovar®) that is adapted to have a coefficient of thermal expansion that is similar to that of the borosilicate glass. The feedthrough conductors 225 and the protective sheaths 227 are suitably sealed (e.g., fused) to one another and the sheaths are suitably sealed (e.g., fused) to the header 203, thereby completely sealing the through holes 221 against passage of the fluid 111 to be analyzed axially though the header, even when the fluid is pressurized. The feedthrough conductors 225 and sheaths 227 can be fused to one another and the header 203, for example, in a firing process known to those skilled in the field of hermetically sealed electronics packaging.

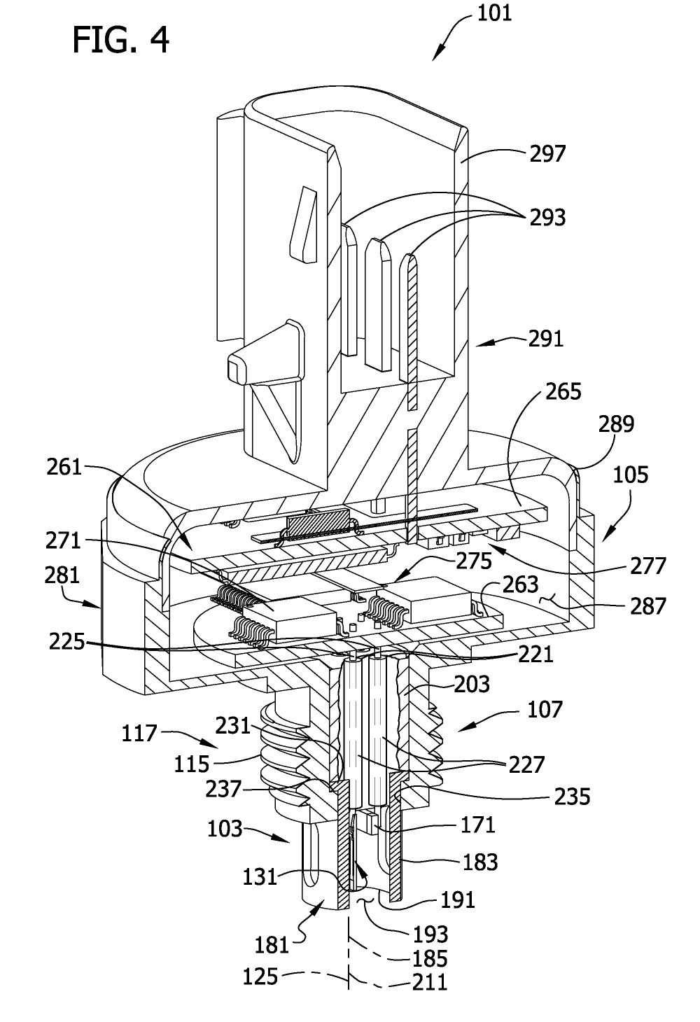

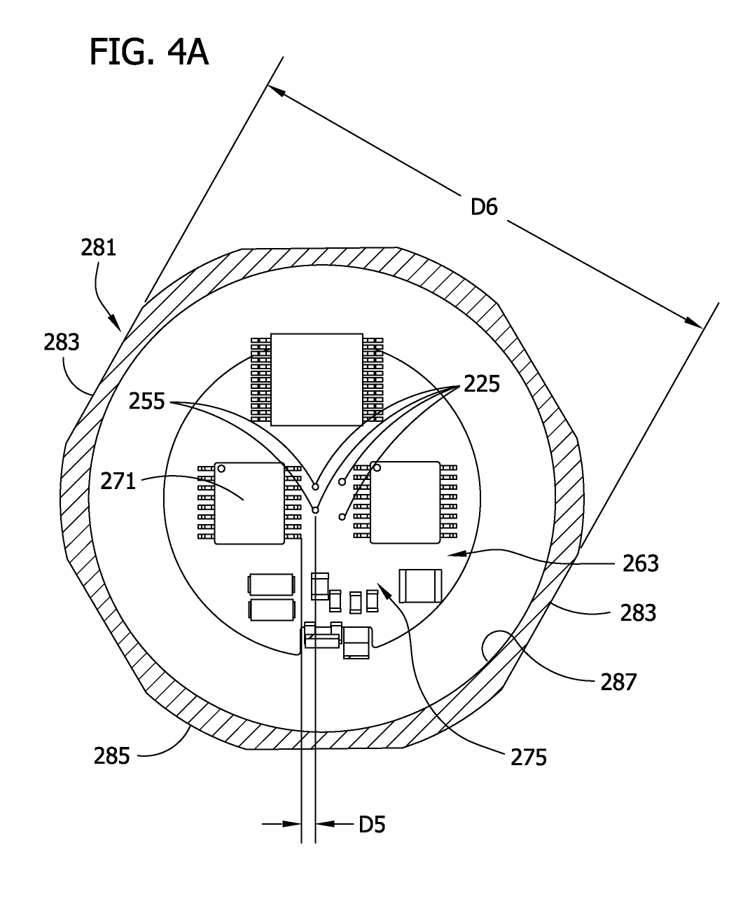

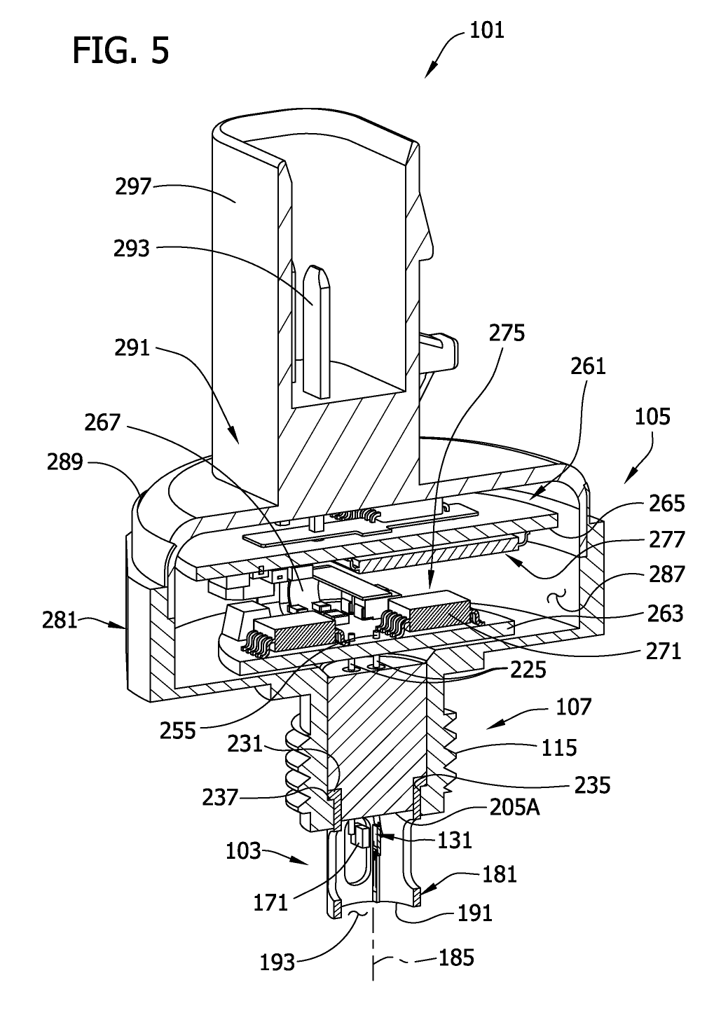

As illustrated in FIGS. 9 and 10, the smaller diameter distal end portion 207 of the header 203 is received in the open proximal end 187 of the shroud 181. The shroud 181 has a radially-outwardly extending flange 231 adjacent the annular shoulder 209 of the header 203. As shown in FIGS. 4 and 5, the header 203 and the proximal end 187 of the shroud 181 in this embodiment are received in a central opening 235 in the threaded ring 115 of the fitting 117. The radially-outwardly extending flange 231 of the shroud 181 is held in place relative to the header 203 by a radially-inwardly extending shoulder 237 on the threaded ring 115 of the fitting 117 adjacent the flange and on the opposite side thereof as the shoulder 209 of the header 203. The header 203 is secured to the fitting 117 by welding, brazing, press fitting, gluing or other suitable techniques, thereby fixedly securing the header and shroud 181 in place relative to the fitting and sealing (e.g., hermetically sealing) the joint between the fitting and the header assembly against flow of the fluid 111 through the joint, even when the fluid is pressurized. When the shroud 181 is secured to the fitting 117 in this manner a portion of the shroud 181 having a length L3, which in one embodiment is suitably in the range of about 7 mm to about 8 mm, protrudes from the fitting 117.

The tuning fork resonator 131 and the temperature sensor 171 are suitably soldered to the conductive feedthrough conductors 225 to secure the tuning fork resonator and the temperature sensor to the header assembly 201. In the illustrated embodiment, the feedthrough conductors 225 space the tuning fork resonator 131 and temperature sensor 171 from the header 203 a distance D10 (FIG. 7) that is suitably in the range of about 1 mm to about 2 mm. In the illustrated embodiment, the tuning fork resonator 131 and temperature sensor 171 are both spaced about the same distance D10 from the header 203. However, this is not required. Further, in some embodiments (not shown) the temperature sensor is spaced farther from the header than the tuning fork resonator to reduce influence the thermal mass of the header may have on temperature measurements taken by the temperatures sensor.

As indicated in FIGS. 9-11, the ends 241 of the feedthrough conductors 225 that are soldered to the tuning fork resonator 131 are shaped to facilitate soldering the feedthrough conductors to the contact pads 161 on the base 147 of the tuning fork resonator. In the illustrated embodiment, the ends 241 of the feedthrough conductors 225 that are connected to the tuning fork resonator 131 are flattened so that relatively wider surfaces 243 of the respective feedthrough conductors 225 face toward the contact pads 161 on the base 147 of the tuning fork resonator 131. The flattened ends 241 are suitably bent inwardly toward one another, thereby facilitating connection of the feedthrough conductors 225 to contact pads that are spaced closer to one another than the spacing D7 between the feedthrough conductors.

In the illustrated embodiment, the tuning fork resonator 131 is connected to the feedthrough conductors 225 on a side 245 of the conductors facing generally inward toward the central axis 211 of the header 203. Thus, in this embodiment, the tuning fork resonator 131 is positioned intermediate the ends 241 of the feed through conductors 225 to which it is connected and the central axis 211 of the header 203. This helps position the tuning fork resonator 131 centrally in the shroud and proximate the central axis 211 of the header 203 while still maintaining sufficient distance D7 between the feedthrough conductors 225 to electrically isolate the feedthrough conductors from one another and allowing the geometric pattern of the plurality of feedthrough conductors to be centered on the central axis of the header 203.

The ends 241 of the feedthrough conductors 225 in one embodiment are suitably coated with a protective material (not shown in the drawings) to protect the exposed portions thereof from corrosion. In one embodiment, for instance, the ends 241 of the feedthrough conductors 225 are plated with a Nickel undercoating (e.g., having a thickness in the range of about 1270 nm to about 2540 nm) to facilitate bonding of a soldering compound 251 to the feedthrough conductors and a Gold overcoating (e.g., having a thickness in the range of about 1270 nm to about 2540 nm) applied over the Nickel coating to help the ends of the feedthrough conductors resist corrosion (e.g., by the fluid 111).

In one embodiment of the invention, the feedthrough conductors 225 are joined to the tuning fork resonator 131 (and optionally the temperature sensor 171) by an electrically conductive soldering compound 251 (FIG. 9) that is substantially free of Tin. Those skilled in the art of soldering will recognize that Tin is a substantial constituent of many common soldering compounds. However, the applicants have found that soldering compounds including substantial amounts of Tin can dissolve the thin overlying Gold layer 165 of the electrodes 151 of the illustrated embodiment of the tuning fork resonator 131. Further, applicants have found that the same soldering compounds do not bond well with the Chromium layer 163 underlying the Gold layer 165 in those electrodes. However, applicants have found that soldering compounds containing Indium instead of Tin (e.g. about seventy percent Indium and about 30 percent Lead) do not dissolve the Gold layer 165 and bond to the Gold layer, thereby achieving results that are superior to soldering compounds that include Tin. In one embodiment, the soldering compound 251 is adapted to begin to liquefy at a temperature in the range of about 165 degrees C. to about 175 degrees C. Suitable Indium soldering compounds, including one designated Indalloy #204, are commercially available from Indium Corp of Utica, N.Y.

The ends 255 of the feedthrough conductors 225 on the opposite side of the header assembly 201 from the sensing portion 103 are electrically connected to the processing portion 105 of the fluid sensor, thereby providing electrical connection between the processing and sensing portions of the fluid sensor 101. In the embodiment illustrated in FIGS. 4-6, the processing portion 105 includes a printed circuit board (PCB) assembly 261. In this embodiment, the PCB assembly 261 includes two PCBs 263, 265 in electrical communication with one another (e.g. via one or more flex cables 267). However, it is understood that all electronic processing components of the processing portion of the sensor may be included on a single PCB, or that there may be more than two PCBs, and/or that the processing portion may include components that are not on any PCB within the scope of the invention.

One of the PCBs 263 is adjacent the header assembly 201 and connected directly to the ends 255 of the feedthrough conductors 255 on the opposite side of the header assembly as the sensing portion 203 (e.g., by a conventional soldering process). This PCB 263 includes electronic systems, generally indicated at 275, on and therein that are operable to energize the electrodes 251 and drive oscillation of the mechanical resonator 131. The electronic systems 275 on and within this PCB 263 are also operable to detect the response of the mechanical resonator 131.

As indicated in FIGS. 4A and 5, in one embodiment this PCB 263 includes an ASIC chip 271 operable to oscillate the mechanical resonator 131 using a variable frequency signal transmitted through the feedthrough conductors 255 and swept over a predetermined range of frequencies and monitor the response of the mechanical resonator to the fluid 111 at various different frequencies of the input signal (e.g., by monitoring impedance of the mechanical resonator as a function of the frequency). One suitable ASIC chip 271 is commercially available from Analog Devices (headquartered in Norwood, Mass.) and designated AD5399. Additional information about suitable ASIC chips is set forth in U.S. Pat. No. 6,873,916, the contents of which are hereby incorporated by reference.

The applicants have found that performance of the fluid sensor 101 can be enhanced by minimizing the total length of the electrically conductive paths between the ASIC chip 271 and the tuning fork resonator 131. One component of the total lengths of the conductive paths is the length of the conductive traces (not shown) in the PCB 263 from the ASIC 271 to the feedthrough conductors 225. The lengths of these conductive traces can be minimized by positioning the ASIC chip 271 on the PCB board 263 so it is relatively close to the feedthrough conductors 225. In one embodiment, for example, the ASIC chip 271 is spaced a distance D5 (FIG. 4A) from the feedthrough conductors 225 that is suitably no more than about 1 mm to about 2 mm. Another component of the total lengths of the conductive paths between the ASIC chip 271 and the tuning fork resonator 131 is the distance D9 (FIG. 6) between the PCB 263 and the contact pads 161 for the electrodes 151 on the tuning fork resonator. The distance D9 is suitably no more than about 20 mm (e.g., in the range of about 15 mm to about 20 mm).

The applicants have also found that performance of the fluid sensor 101 is enhanced by constructing the fluid sensor 101 so the lengths of the conductive paths between the ASIC chip 271 and the contact pads 161 on the tuning fork resonator 131 are about equal. For instance in one embodiment, the total lengths of the conductive paths between the ASIC chip 271 and the tuning fork resonator 131 differ from one another by an amount that is no more than about 1 percent to about 3 percent. By way of example but not limitation, the total lengths of the conductive paths between the ASIC chip 271 and the tuning fork resonator 131 suitably differ from one another by no more than about 0.5 mm in one embodiment.

The flow of electrons through the feedthrough conductors 225 connecting the ASIC chip 271 to the tuning fork resonator 131 is a substantial contributor of noise and other interference because these feedthrough conductors act like antennas when the signal from the ASIC to stimulate the tuning fork resonator is transmitted therethrough. This noise/interference is suitably limited by positioning electrically grounded materials (e.g., the shroud 181, fitting 117, and/or or header 203) around the feedthrough conductors 225. The noise/interference associated with flow of electrons through the feedthrough conductors 225 is also be limited by arranging the feedthrough conductors in a substantially symmetric geometric configuration that is as compact as possible while maintaining a sufficient distance D7 between adjacent feedthrough conductors to limit their interference with one another.

The other PCB 265 in this embodiment is in communication with the first PCB 263 via the one or more flex cables 267. The electronic systems, generally indicated at 277, on and within this PCB 265 include circuitry and components for receiving digitized information about the response of the mechanical resonator 131 and determining one or more properties of the fluid 111 from the digitized information. For example, in one embodiment this PCB 265 includes circuitry for running curve fitting algorithms on the data and using an equivalent circuit (e.g., as described in more detail in U.S. Pat. No. 7,272,525, the contents of which are incorporated herein by reference) to determine one or more properties of the fluid 111. In one embodiment, the electronic systems 277 on this PCB 265 also include circuitry for running algorithms using the determined properties of the fluid 111 (e.g., in combination with historical data and data from the temperature sensor) to determine whether or not the fluid is contaminated, degraded, or otherwise suboptimal.

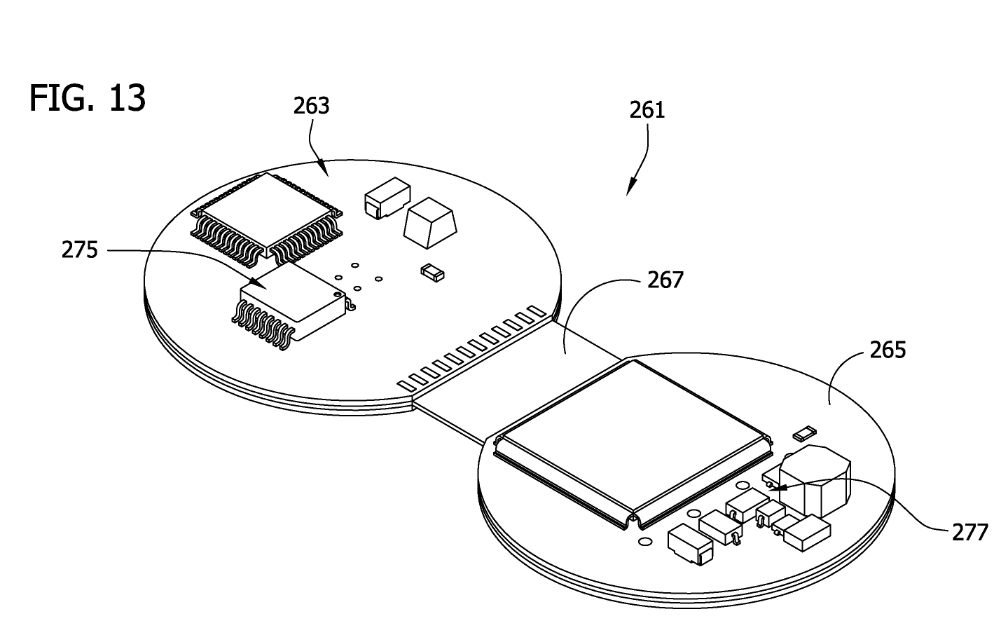

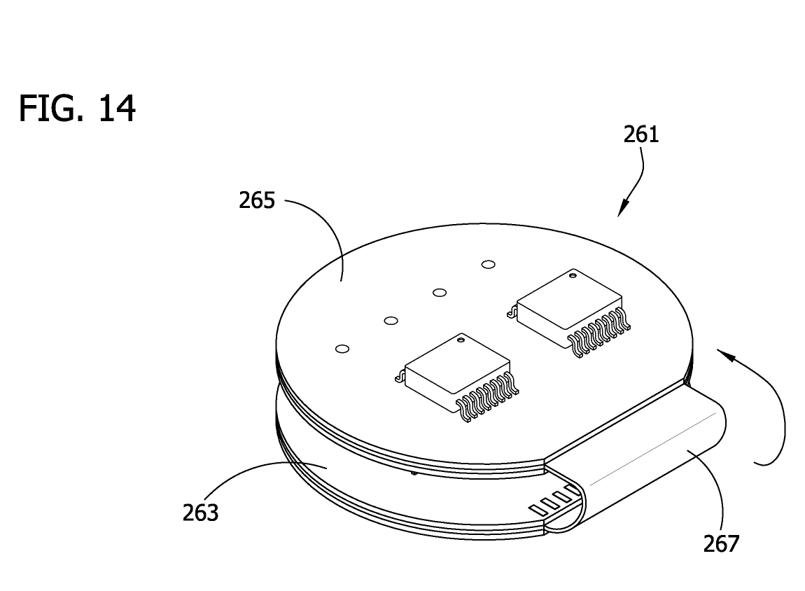

One embodiment of a method of making a suitable PCB assembly 261 is illustrated in FIGS. 13 and 14. As illustrated in FIG. 13, the PCBs 263, 265 are made by attaching the electrical systems and components thereto while the PCBs are in a flat (e.g., substantially co-planar) configuration. For example, the PCBs 263, 265 can be positioned side-by-side and connected to one another by the flex cable(s) 267 while the electrical components 275, 277 are added to the PCBs. According to one embodiment, the PCBs are tested after all the components 275, 277 of the PCBs have been added and while the PCBs are still in the flat configuration.

This facilitates complete testing of the PCB assembly 261 while the PCB assembly is isolated from other parts of the fluid sensor 101 (e.g. before the PCB assembly is combined in any way with other parts of the fluid sensor). Manufacturing the PCB assembly 261 in this way provides additional advantages because it facilitates acquisition of calibration data (e.g., for the temperature sensor) that can be obtained before the PCB assembly 261 is assembled with other parts of the sensor 101. After testing of the PCB assembly 261 and acquisition of calibration data is complete, the PCB assembly is reconfigured to a more compact configuration (FIG. 14), e.g., by folding the PCB assembly 261 upon itself using the flexibility of the flex cable(s) 267. In the embodiment illustrated in FIG. 14, the more compact configuration is one in which one PCB 265 is on top of the other 263. The PCB assembly 261 is suitably in its more compact configuration in the completed fluid sensor 101 to minimize space occupied by the processing portion 105 of the sensor 101. Although, there may be some advantages to the foregoing method of manufacturing the PCB assembly 261, it is understood that sensors having processing systems manufactured by other methods, including methods that do not involve reconfiguring the PCB assembly or any electronic components of the processing portion of the sensor, are within the scope of the invention.

In the embodiment of the fluid sensor 101 illustrated in the drawings, the fitting 117 comprises a housing 281 secured to the threaded ring 115. For example, the housing 281 and threaded ring 115 are suitably integrally formed with one another, as indicated in FIG. 4. As illustrated in FIGS. 1 and 4A, the housing 281 is suitably configured as a hollow nut having a plurality of surfaces (e.g., flats 283) facing radially outwardly (relative to the central axes 185, 211 of the shroud 181 and header assembly 201) that are configured to be engaged by suitable tooling (not shown) for installing the fluid sensor 101 in the opening 121 of the support structure 109. In one embodiment, the surfaces 283 are suitably configured to be engaged by standardized tooling already in use in various industries (e.g., a standard 1.25 inch deep socket, which is commonly used to install sensors in the truck and automotive industry), thereby minimizing changes that are required to assembly lines and other manufacturing processes in order to substitute the fluid sensor 101 for another sensor already being installed by the assembly line or other process.

In the illustrated embodiment, the nut 281 includes six flats 283 arranged in three pairs so that the flats in each pair are on opposite sides of the nut (e.g., on opposite sides of the central axis 211 of the header assembly 201). In the illustrated embodiment, the flats 283 are separated from one another by rounded surfaces 285. However, the nut can have flats that are adjacent one another within the scope of the invention. The nut 281 suitably has a relatively wide configuration for enabling the tooling to fit over the entire processing portion 105 of the fluid sensor 101. In one embodiment, for example, each flat 283 in a pair is spaced from its counterpart a distance D6 (FIG. 4A) that is suitably at least about 1.25 inches (about 32 mm) and more suitably in the range of about 1 inch (about 25 mm) to about 1.5 inches (about 40 mm). In another embodiment, the footprint of the nut 281 when viewed from a vantage point on the central axis 211 of the header assembly 211 (e.g., as in FIG. 4A) is larger than and circumscribes the footprints of all other components of the fluid sensor 101.

As illustrated in FIG. 11, the housing 281 has an open end 289 for receiving the PCB assembly 261 at least partially in the housing during assembly. The fluid sensor 101 also has an electrical connector 291 (e.g., a socket or plug) for connecting the processing portion 105 of the sensor, e.g., via a standardized electrical cable (not shown), to other systems (such as an engine control unit, process controller, machine control system, and the like). In the illustrated embodiment, the electrical connector 291 is received in the open end 289 of the housing 281. Further, the housing 281 and the electrical connector 291 are suitably sealed to one another to hermetically seal the PCB assembly 261 within the volume 287 enclosed by the housing and electrical connector. For example, in one embodiment, a bead of sealant (not shown) such as a silicone sealant is positioned to extend circumferentially around the open end 289 of the housing 281 and contact both the housing and the electrical connector 291. As indicated in FIGS. 4 and 5, the open end 289 of the housing 281 is suitably crimped over the electrical connector 291 to hold the electrical connector in a position relative to the housing that seals the PCB assembly 261 within the enclosed volume 287.

The void space 287 in the nut 281 is suitably partially or completely filled with a potting material (not shown) to protect the PCB assembly 261 from damage from harsh thermal conditions, mechanical shocks, vibrations, and contaminants (including liquid and particulate contaminants). The potting material can also be used as a tamper-evident feature to limit unauthorized tampering with the PCB assembly both before and after the PCB assembly is assembled with the rest of the fluid sensor. Suitable potting materials include epoxy, silicone, and the like.

In the illustrated embodiment, the electrical connector 291 comprises a socket 297 for interfacing with a standardized electrical plug (not shown) of the electrical cable. As illustrated in FIG. 4, the socket 297 is suitably made by overmolding a moldable material over a plurality of electrical contact blades 293 (e.g., four in the illustrated embodiment). The electrical contact blades 293 are electrically connected to the PCB assembly 261 in a conventional manner to provide electrical power to the processing portion 105 of the fluid sensor 101 and transmit information between the processing portion of the sensor 101 and another object (e.g., an engine control unit) via the electrical cable. In one embodiment, the distance D11 (FIG. 2) from the end 191 of the sensing portion to the end 299 of the electrical connector 291 at the opposite end of the sensor is no more than about 75 mm (e.g., no more than about 60 mm).

The fluid sensor 101 is adapted for use in applications in which the sensing portion 103 is subjected to relatively high pressures. For example, in one embodiment the fluid sensor 101 is suitably operable in an environment in which the sensing portion is subjected a pressures up to about 100 psi, and more suitably up to about 500 psi, more suitably up to about 1500 psi, and more suitably up to about 6000 psi, in each case with substantially no leakage of the fluid 111 being analyzed through the header assembly 203. The fluid sensor 101 can also operate at pressures that are substantially less than atmospheric. The ability of the fluid sensor 101 to operate over a wide range of pressures facilitates use of the fluid sensor in a wide range of applications including:
(a) monitoring the condition of engine oil, transmission fluid, fuel or other fluids in a vehicle;
(b) monitoring the condition of hydraulic fluid in a relatively high pressure hydraulic system;
(c) monitoring the condition of lubricants and other fluids associated with operation of an engine;
(d) monitoring the condition of lubricants associated with operation of a refrigeration circuit;
(e) monitoring the condition of fluids associated with the operation of compressors, turbines, or gearboxes;
(f) monitoring the condition of fluids associated with other machines having lubricated gears or bearings; and
(g) monitoring the condition of fluids associated with operation of hydraulically controlled machines.

The fluid sensor 101 is also adapted for use in applications involving a wide range of different kinds of fluids, including both liquids and gases. For example, the fluid sensor 101 is also resistant to corrosion by a wide range of fluids. As noted above, in one embodiment, the electrodes 151 that are used to apply an electric field to the piezoelectric material 143 for oscillating the mechanical resonator 131 comprise a chemically resistant substance (e.g., Gold). Likewise, a chemically resistant material (e.g., Gold) coats the ends of the feedthrough conductors 225 that protrude from the header 203 to protect the feedthrough conductors from corrosion (e.g., by the fluid 111 being analyzed). Further, in one embodiment, all wetted surfaces of the sensing portion 103 and header assembly 201 (including the shroud 181, the mechanical resonator 131, the temperatures sensor 171, the soldering compound 251, the ends 241 of the feedthrough conductors, and the distal end of the header assembly 201) are covered with a protective polymer coating 295 (illustrated on the tuning fork resonator 131 in FIG. 8). In one embodiment the polymer coating has a thickness in the range of about [?].

Moreover, the fluid sensor 101 is suitable for installation in locations in which the fluid 111 to be analyzed is flowing. In many applications, higher fluid pressures are associated with parts of the fluidic system in which the fluid 111 is flowing. The hermetically sealed header assembly 203 facilitates installation of the fluid sensor 101 in these locations notwithstanding the higher fluid pressures. The shroud 181 also facilitates installation of the fluid sensor 101 in a location in which the sensing portion 103 encounters fluid 111 that is flowing because it protects the tuning fork resonator and temperature sensor from impact with debris carried along with the flow and also because the multiple openings 195 therein facilitate flow of fluid through the shroud.

On the other hand, fluid contaminants that could adversely affect performance of the fluid sensor 101 tend to accumulate in sumps, reservoirs, and other parts of the fluidic system that are associated with reduced velocity fluid flows. Accordingly, the ability to install the fluid sensor 101 in a location associated with higher rates of fluid flow, facilitates installation of the fluid sensor in locations selected to limit the adverse impact of contaminants in the fluid 111 on performance of the sensor by positioning the sensor away from parts of the fluidic system having higher concentrations of contaminants.

When introducing elements of the present invention or the preferred embodiments thereof, the articles “a”, “an”, “the”, and “said” are intended to mean that there are one or more of the elements. The terms “comprising”, “including”, and “having” are intended to be inclusive and mean that there may be additional elements other than the listed elements.

As various changes could be made in the above constructions and methods without departing from the scope of the invention, it is intended that all matter contained in the above description and shown in the accompanying drawings shall be interpreted as illustrative and not in a limiting sense.

What is claimed is:

1. A fluid sensor for determining properties of a fluid, the sensor comprising:
a header assembly comprising an electrically grounded header and a plurality of feedthrough conductors extending through the header between opposite ends of the header, each of the feedthrough conductors being surrounded by an electrically insulating sheath, the feedthrough conductors being fused to the sheaths and the sheaths being fused to the header;
a tuning fork resonator having a base portion and a pair of tines extending from the base portion, each of the tines including a piezoelectric substrate and electrodes on the substrate for applying an electric field to the substrate, some of the feedthrough conductors being in conductive electrical contact with the electrodes;
a temperature sensor in conductive electrical contact with some of the feedthrough conductors, the temperature sensor being spaced from the tuning fork resonator a distance that is no more than about 2 mm;
an electrically grounded shroud partially enclosing the tuning fork resonator and temperature sensor, the shroud comprising a substantially cylindrical wall extending circumferentially around the tuning fork resonator and temperature sensor, the shroud including a plurality of openings in the wall for allowing said fluid to enter the shroud and contact the tuning fork resonator and temperature sensor, the shroud being secured to the header assembly;
a fitting adapted to be installed in an opening of a support structure, the fitting having a central opening, the header assembly being received in the central opening and secured to the fitting;
a printed circuit board in conductive electrical contact with the feedthrough conductors, the printed circuit board including an ASIC chip operable to transmit a variable frequency signal to the electrodes on the tuning fork resonator through the feedthrough conductors to energize the electrodes so the tines oscillate in opposite phase and to monitor impedance of the tuning fork resonator as a function of frequency, the ASIC chip being spaced from the feedthrough conductors a distance of no more than about 2 mm, the printed circuit board being spaced from the electrodes on the tuning fork a distance of no more than about 20 mm.

2. A fluid sensor as set forth in claim 1 wherein the piezoelectric substrate comprises quartz.

3. A fluid sensor as set forth in claim 1 wherein the piezoelectric substrate comprises lithium niobate.

4. A fluid sensor as set forth in claim 1 wherein the temperature sensor is an RTD sensor.

5. A fluid sensor as set forth in claim 1 wherein the fitting comprises a threaded ring having external threads for installing the fluid sensor in threaded opening of the support structure.

6. A fluid sensor as set forth in claim 6 wherein the fitting further comprises a housing secured to the threaded ring, the printed circuit board being at least partially received in the housing.

7. A fluid sensor as set forth in claim 6 wherein the housing comprises a nut configured for being engaged by a tool to facilitate installation of the fluid sensor in the opening.

8. A fluid sensor as set forth in claim 6 wherein the printed circuit board is hermetically sealed within the housing.

9. A fluid sensor as set forth in claim 1 wherein the temperature sensor is adjacent the base portion of the tuning fork resonator.

10. A method of making a printed circuit board assembly for a fluid sensor comprising a piezoelectric tuning fork resonator and a temperature sensor, the method comprising:
attaching a first set of electrical components to a first printed circuit board and attaching a second set of electrical components to a second printed circuit board connected to the first printed circuit board by a flex cable, the first and second printed circuit boards being in a first configuration while the electrical components are being attached, the first set of electrical components including an ASIC chip adapted to: (a) oscillate the tuning fork resonator using a variable frequency signal swept over a predetermined range of frequencies; and (b) monitor the response of the mechanical resonator to the fluid at various different frequencies, at least one of the first and second set of electrical components including circuitry for operating the temperature sensor;
testing at least some of the electrical components on at least one of the first and second printed circuit boards while they are in said first configuration;
calibrating one or more electrical components on at least one of the first and second printed circuit boards while they are in said first configuration; and
reconfiguring the first and second printed circuit boards to a second configuration for installation in the fluid sensor, the second configuration being a more compact configuration than the first configuration.

11. A method as set forth in claim 10 wherein the first and second printed circuit boards are substantially co-planar and in side-by-side relation to one another in said first configuration.
